(19) United States
(12) Patent Application Publication
(10) Pub. No.: US 2007/0123032 A1
(43) Pub. Date: May 31, 2007

(54) Method for manufacturing a semiconductor device having a stepped through-hole

(75) Inventor: Kazuo Yamazaki, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/604,727

(22) Filed: Nov. 28, 2006

(30) Foreign Application Priority Data
Nov. 29, 2005 (JP) 2005-344208

(51) Int. Cl. H01L 21/4763

(52) U.S. Cl. 438/624

(57) ABSTRACT

A DRAM device includes a contact plug in contact with a diffused region of a semiconductor substrate, and a via-plug in contact with top of the contact plug. The through-hole receiving the via-plug has stepped structure including a tapered upper portion formed by an anisotropic dry etching and a larger-diameter lower portion formed by an isotropic etching. The top of the contact plug has a diameter larger than the diameter of the bottom of the lower portion of the via-plug.

### BACKGROUND OF THE INVENTION

(a) Field of the Invention

The present invention relates to a method for manufacturing a semiconductor device having a stepped through-hole. The present invention also relates to such a semiconductor device.

(b) Description of the Related Art

A semiconductor device generally has therein a large number of through-holes formed in an interlevel dielectric film overlying a semiconductor substrate. The through-holes are filled with a via-plug for connecting an interconnect line underlying the interlevel dielectric film to another interconnect line overlying the interlevel dielectric film.

A process for forming the through-holes includes the steps of forming a dielectric film overlying the semiconductor substrate, forming a photoresist film on the dielectric film by using a coating technique, patterning the photoresist film to form a photoresist mask having therein a through-hole pattern, and etching the dielectric film in an anisotropic etching process using the photoresist mask as an etching mask. Along with development of finer patterns for the interconnect lines, a higher accuracy is required in the location of the through-holes for achieving accurate alignment of the through-holes with respective interconnect lines.

A self-align-contact (SAC) technique is known as one of the techniques for forming the through-holes, to achieve a higher accuracy in the location of the through-holes. The SAC technique is such that the through-holes are formed in the dielectric film at the position thereof exposed from an overlying interconnect structure and thus contact with the corresponding interconnect structure. The SAC technique has a variety of restrictions in the etching condition, however. The restrictions include a higher etch selectivity to be achieved between the hard mask configuring the top surface of the interconnect structure and the dielectric film to be etched, to prevent the interconnect lines from being exposed from the hard mask. In addition, a smaller-diameter of the through-holes required in view of the underlying smaller-width interconnect lines makes it difficult to form the through-holes by using the SAC technique without involving the problem of an etch stop failure. The etch stop failure generally occurs during forming smaller-diameter through-holes.

A shrinking technique is known as a technique having a less number of restrictions in the etching condition, such as for preventing the etch stop failure in the process for forming the through-holes. The shrinking technique is such that the diameter of openings existing in the photoresist mask is reduced by treating the photoresist mask with a relaxing material. The shrinking technique is described in Patent Publication JP-5(1993)-166717, for example.

The shrinking technique effectively reduces the diameter of openings formed in the photoresist mask, thereby reducing the diameter of the through-holes formed in the photoresist mask down to below the resolution-limited dimension of the exposure system used for patterning the photoresist mask. Thus, the shrinking technique can be used for forming smaller-diameter through-holes without using the SAC technique.

It is known that the through-holes formed by an anisotropic etching technique has a smaller diameter as viewed toward the bottom thereof, wherein the reduced diameter of bottom of the through-holes increases the contact resistance between the via-plug formed in the through-holes and the underlying interconnect lines. The increase of the contact resistance hinders a high-speed operation of the semiconductor device. This problem is especially critical in the technique which achieves a smaller diameter for the through-holes, such as the shrinking technique.

### SUMMARY OF THE INVENTION

In view of the above problems in the conventional techniques, it is an object of the present invention to form through-holes in a semiconductor device by using a shrinking technique substantially without involving the problem of the increased contact resistance.

It is another object of the present invention to provide such a semiconductor device.

The present invention provides a method for manufacturing a semiconductor device comprising the steps of: forming a dielectric film overlying a semiconductor substrate; forming an upper portion of a through-hole by etching an upper section of said dielectric film; forming a sidewall protective film on a sidewall of said upper section; and forming a lower portion of aid through-hole extending from said upper portion by etching a lower section of said dielectric film in an isotropic etching process.

The present invention also provides a semiconductor device comprising: a first dielectric film overlying a semiconductor substrate and receiving a contact plug penetrating through said first dielectric film; a second dielectric film formed on said first dielectric film and receiving a lower portion of a via-plug penetrating through said second dielectric film, said lower portion having a bottom in contact with a top of said contact plug; and a third dielectric film formed on said second dielectric film and receiving an upper portion of said via-plug penetrating through said third dielectric film, said upper portion having a bottom in contact with a top of said lower portion, said top of said lower portion having a diameter larger than a diameter of said bottom of said upper portion, said top of said contact plug having a diameter larger than a diameter of said bottom of said lower portion.

In accordance with the semiconductor device of the present invention and a semiconductor device manufactured by the method of the present invention, the stepped structure of the via-plug formed in the through-hole, wherein the top of the lower portion has a larger diameter than the bottom of the upper portion, increases the contact area between the via-plug and the contact plug, thereby reducing the contact resistance therebetween.

The above and other objects, features and advantages of the present invention will be more apparent from the following description, referring to the accompanying drawings.

### BRIEF DESCRIPTION OF THE DRAWINGS

FIG. 1 is a sectional view of a semiconductor device according to an embodiment of the present invention.

FIGS. 2A to 2E are sectional views of the semiconductor device of FIG. 1 in consecutive steps of fabrication thereof.

FIG. 3 is a sectional view of another semiconductor device shown as a comparative example of the present invention.

### PREFERRED EMBODIMENT OF THE INVENTION

Now, the present invention is more specifically described with reference to accompanying drawings, wherein similar constituent elements are designated by similar reference numerals throughout the drawings.

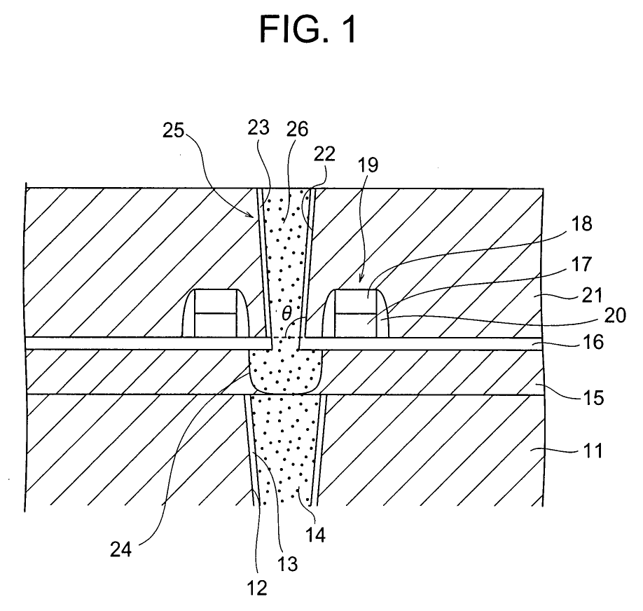

FIG. 1 shows a semiconductor device according to an embodiment of the present invention. The semiconductor device, generally designated by numeral 10, is configured by a DRAM device having a line width of 0.1 μm. The DRAM device 10 includes a semiconductor substrate not shown, a first interlevel dielectric film 11 overlying the semiconductor substrate, and second and third interlevel dielectric film 15, 21 consecutively formed on the first interlevel dielectric film 11. The DRAM device 10 includes nMISFETs (not shown) underlying the first interlevel dielectric film 11 and each including a gate electrode and source/drain regions.

Contact holes 12 are formed in the first interlevel dielectric film 11 to reach the source/drain regions of the semiconductor substrate. The contact holes 12 have a sidewall protective film 13 made of silicon nitride formed on the inner wall of the contact holes 12, and are filled with doped polysilicon (DOPOS) configuring contact plugs 14.

The second interlevel dielectric film 15 has a thickness of 200 to 250 nm. An etch stop layer 16 is interposed between the second interlevel dielectric film 15 and the third interlevel dielectric film 21. The second interlevel dielectric film 15 corresponds to the lower section of the dielectric film defined in the method of the present invention. Bit lines 17 are formed on the etch stop layer 16, and each are covered with an overlying silicon nitride film 18 and a sidewall protective film 20 to form a bit line structure 19.

The bit line structure 19 is covered with the third interlevel dielectric film 21. The third interlevel dielectric film 21 corresponds to the upper section of the dielectric film defined in the method of the present invention. The total thickness of the second interlevel dielectric film 15, etch stop layer 16 and third interlevel dielectric film 21 is roughly 500 nm. The first through third interlevel dielectric films 11, 15 and 21 are made of silicon oxide whereas the etch stop layer 16 is made of silicon nitride (SiN).

Through-holes 25 are formed to penetrate the second interlevel dielectric film 15, etch stop layer 16 and third interlevel dielectric film 21. The through-holes 25 have a stepped structure including an upper portion 22 formed in the third interlevel dielectric film 21 and etch stop layer 16 and a lower portion 24 formed in the second interlevel dielectric film 15. The upper portion 22 of the through-holes 25 is formed by an anisotropic etching process to have a 75-nm-diameter top opening, a smaller-diameter bottom opening, and an intervening extension having a slope angle (θ) of 91.5 degrees with respect to the horizontal plane.

The lower portion 24 of the through-holes 25 is formed by an isotropic etching process to have a diameter of 75 nm, which is significantly larger than the diameter of the upper portion 22.

The upper portion 22 of the through-holes 25 has a sidewall protective film 23 made of silicon nitride having a thickness of 10 to 20 nm on the inner surface thereof, the sidewall protective film 23 having a function of protecting the silicon-oxide surface against the isotropic etching process. The through-holes 25 are filled with a via-plug 26 made of DOPOS. The via-plug 26 has a top surface in contact with a bottom electrode of a capacitor (not shown) overlying the third interlevel dielectric film 21.

The isotropic etching process used for forming the lower portion 24 of the through-holes 25 allows the lower portion 24 to have a larger diameter compared to the bottom of the upper portion 22 of the through-holes 25. This assures a larger contact area between the via-plugs 26 and the underlying contact plugs 14, thereby reducing the contact resistance therebetween.

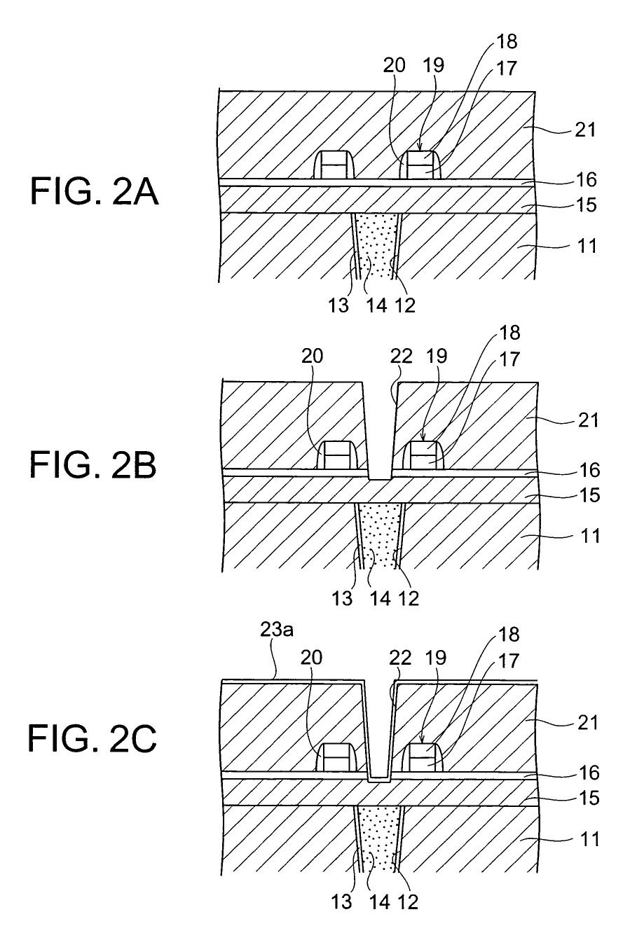

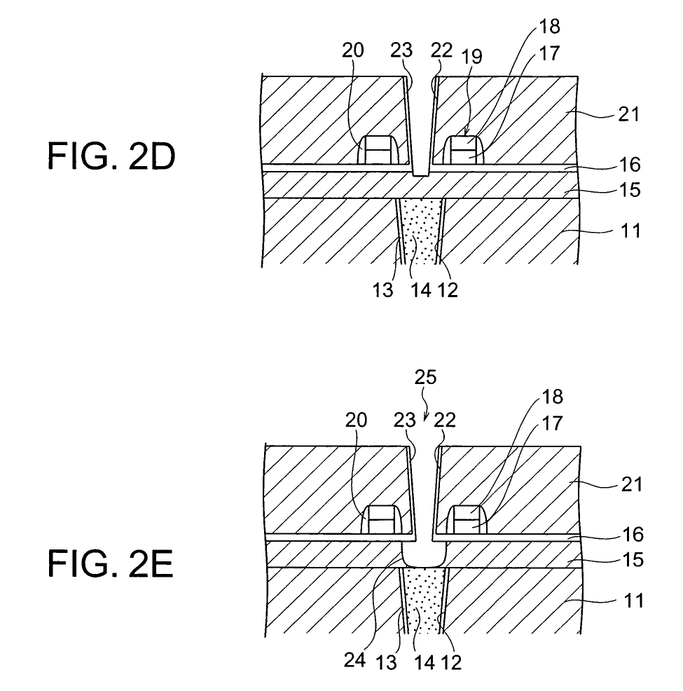

FIGS. 2A to 2E show consecutive steps of fabrication of the semiconductor device of FIG. 1. Gate electrodes (not shown) are formed on a semiconductor substrate, followed by implanting impurities while using the gate electrodes as a mask to thereby form source/drain regions in the semiconductor substrate. Subsequently, the first interlevel dielectric film 11 is formed thereon.

The first interlevel dielectric film 11 is subjected to a known photolithographic and etching process to form therein contact holes 12, followed by depositing silicon nitride on the entire surface including the inner surface of the contact holes 12. The silicon nitride film is then etched back to leave a sidewall protective film 13 on the inner surface of the contact holes 12. A DOPOS film is then deposited within the contact holes 12 to configure contact plugs 14.

The second interlevel dielectric film 15 and etch stop layer 16 are consecutively formed on the first interlevel dielectric film 11 and the contact plugs 14. A tungsten film 17 and a silicon nitride film 18 are then deposited on the etch stop layer 16, and are patterned by etching to form therefrom bit lines 17 and overlying protective film 18. Another silicon nitride film is then deposited and etched back to form a sidewall film 20 on the bit lines 17 to configure the bit line structure 19.

Thereafter, the third interlevel dielectric film 21 is deposited on the etch stop layer 16 and the bit line structure 19 including the bit lines 17, top protective film 18 and sidewall film 20, and is subjected to a chemical mechanical polishing process for planarization, to obtain the structure shown in FIG. 2A.

A photoresist film is then formed on the third interlevel dielectric film 21 and patterned to form therefrom a photoresist mask (not shown). The photoresist mask is then subjected to a shrinking process using a relaxing material, whereby the diameter of openings of the photoresist mask is reduced. The shrunk photoresist mask is then used as an etching mask for patterning the third interlevel dielectric film 21 by using a dry etching technique. The spectrum of luminance from the bottom of a through-hole, which is being formed by the etching of the third interlevel dielectric film 21, is observed to find an etch stop condition, whereby this etching is stopped on the top surface of the etch stop layer 16.

Subsequently, the etch stop layer 16 is etched using the same photoresist mask, thereby completing the upper portion 22 of the through-holes 25, as shown in FIG. 2B. The spectrum of luminance from the bottom of the through-hole 25, which is being formed by the etching of the etch stop layer 16, is observed to find an etch stop condition, whereby this etching is stopped on the top surface of the second interlevel dielectric film 15.

A silicon nitride film 23a is then deposited on the entire surface including the internal of the upper portion 22 of the through holes 25, as shown in FIG. 2C. The silicon nitride film 23a is etched back to remove the portion thereof on top of the third interlevel dielectric film 21 and bottom of the upper portion 22 of the through-holes 25, thereby leaving the sidewall protective film 23 on the sidewall of the upper portion 22, as shown in FIG. 2D.

A wet etching process is then conducted using hydrofluoric acid to etch the portion of the second interlevel dielectric film 15 exposed from the bottom of the upper portion 22 of the through-holes 25, thereby forming the lower portion 24 of the through-holes 25 extending from the upper portion 22, as shown in FIG. 2E. The wet etching of the second interlevel dielectric film 15 is performed for a specified time interval, which is determined based on the etch rate and thickness of the second interlevel dielectric film 15. The lower portion 24 of the through-holes 25 may extend in the lateral direction toward almost the beneath of the tungsten film 17 of the bit line structure 19. The etch stop layer 16 prevents the tungsten film 17 from being exposed through the lower portion 24 of the through-holes 25.

Thereafter, a DOPOS film is deposited within the through-holes 25 to thereby form via-plugs 26, as shown in FIG. 1. Subsequent known processes are conducted for forming overlying capacitors, interlevel dielectric films and interconnect lines, thereby completing the final structure of the DRAM device 10.

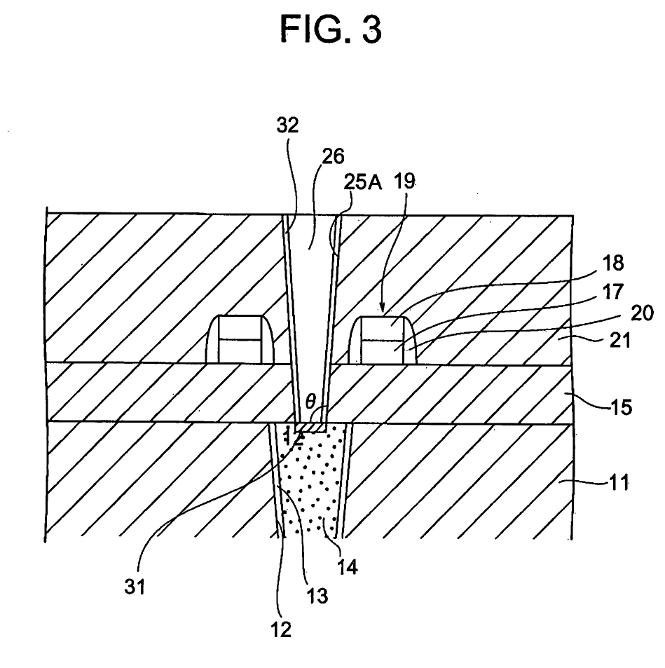

FIG. 3 shows another DRAM device 30, manufactured as a comparative example of the present invention by using a process similar to the above process except that, in the comparative example, the etch stop layer 16 is not provided, the through-holes 25A are formed in a single dry etching process, and the sidewall protective film 32 is formed in the through-holes 25A after the etching for forming the through-holes 25A. The sidewall protective film 32 is provided for preventing a short-circuit failure between adjacent two of via-plugs 26, which may occur due to presence of voids within the interlevel dielectric film 15 or 21.

In manufacture of the comparative example 30, since the through-holes 25A are formed using a dry etching process to expose therefrom the top of the silicon contact plugs 14, the top of the silicon contact plugs 14 may be damaged to form thereon a damaged portion 31, as shown in FIG. 3. The damaged portion 31, if formed, raises the contact resistance between the contact plugs 14 and the via-plugs 26.

On the other hand, in manufacture of the above embodiment, since the lower portion 24 of the through-holes 25 are formed using a wet etching process to expose therefrom the top of the contact plugs 14, the damage 31 incurred on the contact plugs 14 in the comparative example is not generated. This assures a normal contact resistance between the contact plugs 14 and the via-plugs 26.

Assuming that the through-holes 25A in the comparative example are 500-nm deep and has an inclined angle (θ) of 91.5 degrees on the sidewall thereof with respect to the horizontal plane, the bottom of the through-holes 25 has a diameter of around 48 nm. On the other hand, in the DRAM device of the present embodiment, the through-holes 25 have a bottom diameter of 75 nm, which is about 1.56 times the diameter of the through-holes 25A in the comparative example. This assures a sufficient contact area between the contact plugs 14 and the via-plugs 26 in the present embodiment, which is as large as 2.4 times the contact area in the comparative example. Thus, the contact resistance in the present embodiment is reduced down to 1/2.4 of the contact resistance in the comparative example, assuming that the contact resistance is inversely proportional to the contact area.

The lower portion 24 of the through-holes 25 may be formed by an isotropic dry etching process for suppression of the damage on top of the silicon contact plugs 26, instead of using the wet etching process. The etch stop layer 16 may be provided with an intervention film which intervenes between the etch stop layer 16 and the tungsten film 17.

If the intervention film is to be provided between the etch stop layer 16 and the tungsten film 17, the etch stop layer 16 should be preferably provided above the middle point between the bottom of the second interlevel dielectric film 15 and the bottom of the tungsten film 17. The diameter of the bottom of the upper portion 22 of the through-holes 25 should be preferably larger than 30 nm in order for effective suppression of reduction in the operational speed of the DRAM device 10. The via-plug may be made of a metal instead of DOPOS.

Since the above embodiments are described only for examples, the present invention is not limited to the above embodiments and various modifications or alterations can be easily made therefrom by those skilled in the art without departing from the scope of the present invention.

What is claimed is:

1. A method for manufacturing a semiconductor device comprising the steps of:
forming a dielectric film overlying a semiconductor substrate;
forming an upper portion of a through-hole by etching an upper section of said dielectric film;
forming a sidewall protective film on a sidewall of said upper section; and
forming a lower portion of aid through-hole extending from said upper portion by etching a lower section of said dielectric film in an isotropic etching process.

2. The method according to claim 1, wherein said dielectric film forming step includes forming an etch stop layer between said upper section and said lower section of said dielectric film, and said upper portion forming step includes an anisotropic etching stopped by said etch stop layer.

3. The method according to claim 2, further comprising the step of forming a plurality of interconnect lines on a top of said etch stop layer, said interconnect lines each having thereon a sidewall and top protective film, wherein said through-holes are formed between adjacent two of interconnect lines.

4. The method according to claim 1, wherein each of said through-holes exposes therethrough a top of a contact plug, and said lower portion of said each of said through-holes has a diameter, which is larger than a diameter of at least a bottom of said upper portion and smaller than a diameter of said top of said contact plug at least in a bottom of said lower portion.

5. The method according to claim 1, wherein said isotropic etching process includes at least one of a wet etching process and an isotropic dry etching process.

6. The method according to claim 1, wherein said upper portion forming step includes the steps of:
forming a resist pattern having an opening exposing therethrough a portion of said dielectric film;
shrinking said opening of said resist pattern; and
etching said upper section of said dielectric film in a dry etching process using said resist pattern having said shrunk opening as an etching mask.

7. A semiconductor device comprising:
a first dielectric film overlying a semiconductor substrate and receiving therein a contact plug penetrating through said first dielectric film;
a second dielectric film formed on said first dielectric film and receiving therein a lower portion of a via-plug penetrating through said second dielectric film, said lower portion having a bottom in contact with a top of said contact plug; and
a third dielectric film formed on said second dielectric film and receiving therein an upper portion of said via-plug penetrating through said third dielectric film, said upper portion having a bottom in contact with a top of said lower portion,
said top of said lower portion having a diameter larger than a diameter of said bottom of said upper portion, said top of said contact plug having a diameter larger than a diameter of said bottom of said lower portion.

8. The semiconductor device according to claim 7, wherein said contact plug includes silicon, and said via-plug includes a metal.

9. The semiconductor device according to claim 7, wherein both said contact plug and said via-plug include silicon.

10. The semiconductor device according to claim 7, wherein said third dielectric film includes an etch stop layer and an overlying interlevel dielectric film, a plurality of interconnect lines are disposed on a top of said etch stop layer, and said through-holes each extend between adjacent two of said interconnect lines.
